(19) United States
(12) Patent Application Publication
(10) Pub. No.: US 2008/0185036 A1
(43) Pub. Date: Aug. 7, 2008

(54) Substrate For Thin Film Photoelectric Conversion Device and Thin Film Photoelectric Conversion Device Including the Same

(76) Inventors: Toshiaki Sasaki, Shiga (JP); Yohei Koi, Shiga (JP); Yuko Tawada, Osaka (JP); Takashi Suezaki, Shiga (JP); Kenji Yamamoto, Hyogo (JP)

Correspondence Address: BIRCH STEWART KOLASCH & BIRCH, PO BOX 747, FALLS CHURCH, VA, 22040-0747, US

(21) Appl. No.: 11/791,754

(22) PCT Filed: Nov. 9, 2005
(86) PCT No.: PCT/JP2005/020512

§ 371 Date: May 29, 2007

(30) Foreign Application Priority Data
Nov. 29, 2004 (JP) 2004-343868
Feb. 4, 2005 (JP) 2005-028720

(51) Int. Cl. H01L 31/04

(52) U.S. Cl. 136/252

(57) ABSTRACT

An object of the present invention is to provide a substrate for a thin film photoelectric conversion device, in which its properties are not deteriorated when its surface unevenness is effectively increased, and then provide the thin film photoelectric conversion device having its performance improved by using the substrate.

According to the present invention, by setting the surface area ratio of a transparent electrode layer in the substrate for the thin film photoelectric conversion device to at least 55% and at most 95%, the surface unevenness are effectively increased to increase the optical confinement effect, while deterioration in properties due to sharpening of the surface level variation is suppressed, whereby making it possible to provide a substrate for a thin film photoelectric conversion device, which can enhance output properties of the thin film photoelectric conversion device.

### TECHNICAL FIELD

The present invention relates to a substrate for a thin film photoelectric conversion device and a thin film photoelectric conversion device including the same.

### BACKGROUND ART

In recent years, in order to simultaneously achieve lower costs and higher efficiency in a photoelectric conversion device, an example of which is a solar cell, attention has been attracted to a thin film photoelectric conversion device that can be formed with a smaller amount of raw material, and development thereof has been tried intensively. A method of forming a high-quality semiconductor layer on an inexpensive base such as a glass plate by low temperature processing is particularly expected as a method capable of achieving lower costs.

Such a thin film photoelectric conversion device generally includes a transparent electrode layer, at least one photoelectric conversion unit, and a back electrode layer successively stacked on a transparent insulator base. Here, the photoelectric conversion unit generally includes a p-type layer, an i-type layer, and an n-type layer stacked in this order or in a reverse order, where the i-type layer occupies a major part of the unit. The photoelectric conversion unit having an amorphous i-type photoelectric conversion layer is referred to as an amorphous photoelectric conversion unit, while the photoelectric conversion unit having a crystalline i-type layer is referred to as a crystalline photoelectric conversion unit.

In fabrication of the thin film photoelectric conversion device, there is used a substrate for the thin film photoelectric conversion device, which includes a transparent electrode deposited on a transparent insulator base. In general, a glass plate is used as the transparent insulator base. On the glass plate, an SnO₂ film of 700 nm thickness, for example, is formed as the transparent electrode layer by a thermal CVD method.

Each photoelectric conversion unit formed on the substrate for the thin film photoelectric conversion device contains p-i-n junctions composed of the p-type layer, the i-type layer that is a substantially intrinsic photoelectric conversion layer, and the n-type layer. The photoelectric conversion unit using amorphous silicon for the i-type layer is referred to as an amorphous silicon photoelectric conversion unit, while the photoelectric conversion unit using substantially crystalline silicon for the i-type layer is referred to as a crystalline silicon photoelectric conversion unit. As the amorphous or crystalline silicon-based material, it is possible to use a semiconductor containing only silicon as a major element and also possible to use an alloyed semiconductor containing an element such as carbon, oxygen, nitrogen, or germanium. As the material mainly constituting the conductive-type layers, it is not necessary to use a material identical to that of the i-type layer. For example, amorphous silicon carbide can be used for the p-type layer, and a silicon layer containing substantially microcrystalline silicon (referred to as μc-Si) can be used for the n-type layer, in the amorphous silicon photoelectric conversion unit.

As the back electrode layer formed on the photoelectric conversion unit, a metal layer such as Al or Ag is formed by a sputtering method or an evaporation method. A layer of a conductive oxide such as ITO, SnO₂, or ZnO may be formed between the photoelectric conversion unit and the metal electrode.

A plate-like or sheet-like member of glass, transparent resin, or the like is used as the transparent insulator base included in the substrate for a photoelectric conversion device of a type which receives light from the substrate side.

The transparent electrode layer is made with a conductive metal oxide such as SnO₂ or ZnO by a method such as of CVD, sputtering, or evaporation. It is preferable that the transparent electrode layer has fine unevenness on its surface to cause an effect of increasing scattering of incident light.

The amorphous silicon photoelectric conversion device, which is an example of the thin film photoelectric conversion devices, has a problem of lower initial photoelectric conversion efficiency and an additional problem of decrease in conversion efficiency due to an light induced degradation phenomenon, when compared with a monocrystalline or polycrystalline photoelectric conversion device. Accordingly, the crystalline silicon thin film photoelectric conversion device using crystalline silicon such as thin film polycrystalline silicon or microcrystalline silicon for its photoelectric conversion layer, has been expected and studied as the device capable of simultaneously achieving lower costs and higher efficiency. This is because the crystalline silicon thin film photoelectric conversion device can be formed at a low temperature by a plasma CVD method, similarly as in the case of forming an amorphous silicon layer, and causes almost no light induced degradation phenomenon. Furthermore, the amorphous silicon photoelectric conversion layer can photoelectrically convert light having a wavelength of up to approximately 800 nm on the long-wavelength side, whereas the crystalline silicon photoelectric conversion layer can photoelectrically convert light having a larger wavelength of up to approximately 1200 nm.

As a method of improving conversion efficiency of the photoelectric conversion device, there is known a photoelectric conversion device adopting a so-called stacked-layer type of structure in which at least two photoelectric conversion units are stacked. In this method, a front photoelectric conversion unit that includes a photoelectric conversion layer having the largest optical forbidden bandgap is placed on the light incident side of the photoelectric conversion device, and backward photoelectric conversion units each including a photoelectric conversion layer having a smaller bandgap are disposed in the decreasing order of the bandgap behind the front unit. Accordingly, photoelectric conversion becomes possible over a wide wavelength range of the incident light, and thus the incident light can be utilized effectively so as to improve the conversion efficiency in the entire device. (In the present application, a photoelectric conversion unit placed relatively close to the light incident side is referred to as a forward photoelectric conversion unit, while a photoelectric conversion unit neighboring on the forward unit and placed relatively farther from the light incident side is referred to as a backward photoelectric conversion unit.)

The thin film photoelectric conversion device can have a photoelectric conversion layer thinner than that of the conventional photoelectric conversion unit using bulky monocrystalline or polycrystalline silicon. On the other hand, it has a problem that light absorption in the entire thin film is limited by the film thickness. Accordingly, in order to more effectively utilize light incident on the photoelectric conversion unit including the photoelectric conversion layer, it is intended to form unevenness (texturing) on a surface of a transparent conductive film or a metal layer neighboring on the photoelectric conversion unit to scatter light at the textured interface and then introduce the scattered light into the photoelectric conversion unit so that the optical path length can be prolonged so as to increase light absorption amount in the photoelectric conversion layer. This technique is referred to as “optical confinement”, which is an important technique element in order to realize the thin film photoelectric conversion device having high photoelectric conversion efficiency.

To determine the shape of surface unevenness of the transparent electrode layer optimal for the thin film photoelectric conversion device, it is needed to use an index quantitatively representing the shape of surface unevenness. Conventionally, the haze ratio, arithmetic mean roughness (Rₐ), and root mean square roughness (RMS) are generally used as the indexes representing the shape of surface unevenness.

The haze ratio is an index for optically evaluating surface unevenness of a transparent substrate, and is expressed by (diffusion transmittance/total transmittance)×100 [%] (JIS K7136). For measurement of the haze ratio, a haze meter capable of automatically measuring the haze ratio is commercially available and enables easy measurement. In general, the C light source is used as a light source used for the measurement.

The arithmetic mean roughness is also referred to as centerline mean roughness, mean roughness, or Roughness Average of the Surface, and is abbreviated as Rₐ or Sa. Given that Z represents the height in a direction vertical to the substrate and Zₐᵥₑ represents the mean value of the height, Rₐ is defined by formula 1 as to the three-dimensional shape of surface unevenness.

$$\begin{matrix}[ Expression 1 ] & \\ {R}_{a} = \frac{1}{MN} {\sum }_{j = 1}^{M} {\sum }_{k = 1}^{N} \vert Z ( {x}_{j} , {y}_{k} ) - {Z}_{ave} \vert & ( formula 1 )\end{matrix}$$

Note that the number of measurement points is M×N. Z(xⱼ, yₖ) is a height at coordinates (xⱼ, yₖ), and Zₐᵥₑ is a mean value of the heights at M×N points. Formula 1 shows that Rₐ is a mean value of absolute values of differences between the heights at respective points and Zₐᵥₑ. Rₐ can be measured by means of a scanning microscope such as an atomic force microscope (AFM) or a scanning tunneling microscope (STM).

The root mean square roughness is also referred to as Root-Mean-Square Deviation of the Surface, and is abbreviated as RMS or S_{q}. When the three-dimensional shape of surface unevenness is to be determined, RMS is defined by formula 2 (ISO4287/1).

$$\begin{matrix}[ Expression 2 ] & \\ {S}_{q} = \sqrt{\frac{1}{MN} {\sum }_{j = 1}^{M} {\sum }_{k = 1}^{N} {( Z ( {x}_{j} , {y}_{k} ) - {Z}_{ave} )}^{2}} & ( formula 2 )\end{matrix}$$

Formula 2 shows that RMS is determined by averaging the squares of the differences between the heights Z(xⱼ, yₖ) at respective points and Zₐᵥₑ and then obtaining the square root of the averaged square. Similarly as in the case of Rₐ, RMS can be measured with a scanning microscope such as an AFM or an STM.

### Prior Art Example 1

Patent Document 1 discloses an example of a thin film photoelectric conversion device in which a substrate for the device is formed by depositing ZnO for a transparent electrode layer on a glass base, and amorphous silicon is used for a semiconductor film. It is preferable that the transparent electrode layer has surface unevenness as large as possible to enhance the optical confinement effect. However, it is pointed out that excessively large surface unevenness hinders growth of the thin film semiconductor layer and may cause deterioration in properties of the thin film photoelectric conversion device. Specifically, it is stated that, when Rₐ is used as an index of the surface unevenness, Rₐ should preferably be in a range of at least 0.1 μm and at most 2 μm. Rₐ of less than 0.1 μm is undesirable because the uneven surface optically resembles a flat surface, and hence weakens the optical confinement effect. Rₐ of more than 2 μm is also undesirable because it hinders growth of the thin film semiconductor layer, and hence causes deterioration in film quality.

Patent Document 1: Japanese Patent Laying-Open No. 2003-115599

### DISCLOSURE OF THE INVENTION

### Problems to be Solved by the Invention

The inventors fabricated substrates for the thin film photoelectric conversion devices such that the transparent electrode layers in the substrates had various shapes of surface unevenness, and carefully studied the properties of the thin film photoelectric conversion devices including the same. Contrary to prior art example 1, there was found a problem that growth of the thin film semiconductor layer may be hindered even in the case of Rₐ not more than 2 μm and then there may be caused significant decrease in Voc and FF of the thin film photoelectric conversion devices.

Furthermore, it was found that there does not necessarily exists a clear correlation between the magnitude of haze ratio, Rₐ, or RMS and the properties of the thin film photoelectric conversion devices, so that it was revealed that the haze ratio, Rₐ and RMS cannot be regarded as a favorable index of the surface unevenness of the substrates for the thin film photoelectric conversion devices.

In view of the problems as above, an object of the present invention is to provide a substrate for a thin film photoelectric conversion device, which does not cause deterioration in properties when the surface unevenness thereof is effectively increased, and provide a thin film photoelectric conversion device having its performance improved by using the substrate.

### Means for Solving the Problems

A substrate for a thin film photoelectric conversion device according to the present invention includes a transparent insulator base and a transparent electrode layer deposited thereon, wherein a surface of the transparent electrode layer has a surface area ratio of at least 55% and at most 95%, thereby effectively increasing the surface unevenness to increase the optical confinement effect while suppressing deterioration in properties thereof, and making it possible to provide a substrate for a thin film photoelectric conversion device, which can enhance properties of the thin film photoelectric conversion device.

The transparent electrode layer preferably contains at least zinc oxide, so that it is possible to provide at low costs a substrate having a surface area ratio in an optimal range for a thin film photoelectric conversion device.

Preferably, the transparent insulator base is mainly composed of a glass plate, so that it is possible to provide an inexpensive high-transmittance substrate for a thin film photoelectric conversion device.

A thin film photoelectric conversion device including at least one photoelectric conversion unit and a back electrode layer stacked in this order on such a substrate for a thin film photoelectric conversion device as defined by the present invention is inexpensive and has excellent properties.

### EFFECTS OF THE INVENTION

According to the present invention, by using a surface area ratio as an index of surface unevenness of the substrate for the thin film photoelectric conversion device, it is possible to determine the shape of surface unevenness suitable for the thin film photoelectric conversion device. Furthermore, by setting the surface area ratio to at least 55% and at most 95%, it is possible to effectively increase the surface unevenness to increase the optical confinement effect while suppressing deterioration in properties thereof, and it becomes possible to provide a substrate for a thin film photoelectric conversion device, which can enhance properties of the thin film photoelectric conversion device.

### BRIEF DESCRIPTION OF THE DRAWINGS

FIG. 1 shows a structure including a substrate for a thin film photoelectric conversion device and the thin film photoelectric conversion device.

FIG. 2 is an explanatory diagram of S_{dr}.

FIG. 3 is a correlation diagram of Eff with respect to Rₐ.

FIG. 4 is a correlation diagram of Jsc with respect to Rₐ.

FIG. 5 is a correlation diagram of FF with respect to Rₐ.

FIG. 6 is a correlation diagram of Voc with respect to Rₐ.

FIG. 7 is a correlation diagram of Eff with respect to RMS.

FIG. 8 is a correlation diagram of Eff with respect to Hz.

FIG. 9 is a correlation diagram of Hz with respect to Rₐ and RMS.

FIG. 10 is a correlation diagram of Eff with respect to S_{dr}.

FIG. 11 is a correlation diagram of Jsc with respect to S_{dr}.

FIG. 12 is a correlation diagram of FF with respect to S_{dr}.

FIG. 13 is a correlation diagram of Voc with respect to S_{dr}.

FIG. 14 is a correlation diagram of Hz with respect to S_{dr}.

### DESCRIPTION OF THE REFERENCE SIGNS

1: substrate for photoelectric conversion device, 11: transparent insulator base, 111: fundamental transparent base, 112: transparent underlayer, 1121: transparent fine particles, 1122: transparent binder, 12: transparent electrode layer, 2: front photoelectric conversion unit, 21: one conductivity type of layer, 22: photoelectric conversion layer, 23: opposite conductivity type of layer, 3: back photoelectric conversion unit, 31: one conductivity type of layer, 32: photoelectric conversion layer, 33: opposite conductivity type of layer, 4: back electrode layer, 41: conductive oxide layer, 42: metal layer, 5: thin film solar cell.

### BEST MODES FOR CARRYING OUT THE INVENTION

A preferable embodiment of the present invention will hereinafter be described with reference to the drawings. In the drawings of the present application, dimensions such as thickness and length are modified as appropriate for clarity and simplification of the drawings, so that actual dimensional relations are not shown. In the drawings, the same reference character represents the same or corresponding portion.

Although it is preferable to increase the surface unevenness in order to enhance the optical confinement effect, it is pointed out that such increase of the surface unevenness may cause sharper level variation and then may cause deterioration in properties of the thin film photoelectric conversion device. With the sharper level variation, there occurs decrease in the open-circuit voltage (Voc) and fill factor (FF), and hence decrease in the conversion efficiency (Eff), as to the properties of the thin film photoelectric conversion device. In some cases, the short-circuit current density (Jsc) is also decreased.

The reason for the deterioration in properties of the thin film photoelectric conversion device is considered as follows. If the level variation becomes sharper and then acute-angular protrusions and gorge-like recesses are formed on the transparent electrode layer, growth of the thin film semiconductor layer is hindered thereby, so that the transparent electrode layer cannot uniformly be covered with the semiconductor layer and then so-called “poor-coverage” occurs. As a result, there occurs increase in the contact resistance and leakage current, which causes decrease mainly in Voc and FF, and hence decrease in Eff. Furthermore, the sharper level variation hinders growth of the semiconductor layer over the transparent electrode layer, deteriorates film quality of the semiconductor layer, and causes more loss owing to carrier recombination, which then causes decrease in Voc, FF and Jsc, and hence decrease in Eff.

The inventors fabricated substrates for the thin film photoelectric conversion devices such that the transparent electrode layers in the substrates had various shapes of surface unevenness, and carefully studied the properties of the thin film photoelectric conversion devices including the same. Contrary to prior art example 1, there was found a problem that growth of the thin film semiconductor layer may be hindered even in the case of Rₐ not more than 2 μm and then there may be caused significant decrease in Voc and FF of the thin film photoelectric conversion devices.

Furthermore, it was found that there does not necessarily exists a clear correlation between the magnitude of haze ratio, Rₐ, or RMS and the properties of the thin film photoelectric conversion devices, so that it was revealed that the haze ratio, R, and RMS cannot be regarded as a favorable index of the surface unevenness of the substrates for the thin film photoelectric conversion devices.

In order to overcome the problems as above, a careful study was further conducted on the substrates for the thin film photoelectric conversion devices and the photoelectric conversion devices including the same. As a result, it was found that the “surface area ratio” (S_{dr}) is suitable for use as an index of surface unevenness of the substrates for the thin film photoelectric conversion devices. In other words, the substrate for the thin film photoelectric conversion device according to the present invention is characterized in that it has a surface area ratio (S_{dr}) of at least 55% and at most 95%, to overcome the above problems.

The surface area ratio used herein as an evaluation index of surface unevenness is also referred to as a Developed Surface Area Ratio and is abbreviated as S_{dr}. The S_{dr} can be defined by formula 3 and formula 4 (K. J. Stout, P. J. Sullivan, W. P. Dong, E. Manisah, N. Luo, T. Mathia: “The development of methods for characterization of roughness on three dimensions”, Publication no. EUR 15178 EN of the Commission of the European Communities, Luxembourg, pp. 230-231, 1994).

$$\begin{matrix}[ Expression 3 ] & \\ {S}_{dr} = \frac{( {\sum }_{j}^{M - 1} {\sum }_{k}^{N - 1} {A}_{jk} ) - ( M - 1 ) ( N - 1 ) Δ X Δ Y}{( M - 1 ) ( N - 1 ) Δ X Δ Y} \times 100 \% & ( formula 3 )\end{matrix}$$

Note that Aⱼₖ is expressed by the following expression.

$$\begin{matrix}[ Expression 4 ] & \\ {A}_{jk} = \frac{1}{2} [ \sqrt{Δ {Y}^{2} + {\{ Z ( {x}_{j} , {y}_{k} ) - Z ( {x}_{j} , {Y}_{k + 1} ) \}}^{2}} + \sqrt{Δ {Y}^{2} + {\{ Z ( {x}_{j + 1} , {y}_{k} ) - Z ( {x}_{j + 1} , {Y}_{k + 1} ) \}}^{2}} ] \times \frac{1}{2} [ \sqrt{Δ {X}^{2} + {\{ Z ( {x}_{j} , {y}_{k} ) - Z ( {x}_{j + 1} , {Y}_{k} ) \}}^{2}} + \sqrt{Δ {X}^{2} + {\{ Z ( {x}_{j} , {y}_{k + 1} ) - Z ( {x}_{j + 1} , {Y}_{k + 1} ) \}}^{2}} ] & ( formula 4 )\end{matrix}$$

ΔX and ΔY are a distance between measurement points in an X direction and a distance between measurement points in a Y direction, respectively.

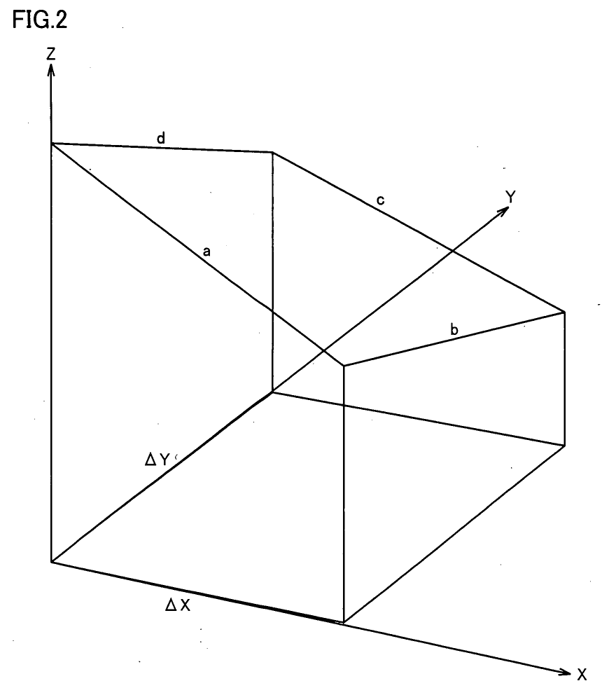

The meaning of formulas 3 and 4 will now be described with reference to FIG. 2. The S_{dr} represents a ratio of surface area increase with respect to a flat area of the XY plane. In other words, S_{dr} becomes larger as the level variation is made larger and sharper. The meaning of S_{dr} can be shown in a more readily understandable manner by formula 5, corresponding to formula 3.

$$\begin{matrix}[ Expression 5 ] & \\ {S}_{dr} = \{ average of \frac{approximate surface area - Δ X Δ Y}{Δ X Δ Y} \} \times 100 \% & ( formula 5 )\end{matrix}$$

Here, the approximate surface area is expressed by formula 6.

$$\begin{matrix}[ Expression 6 ] & \\ approximate surface area = \frac{( a + c )}{2} \times \frac{( b + d )}{2} & ( formula 6 )\end{matrix}$$

Note that each of a, b, c and d is a length of line segment between adjacent measurement points. Similarly as in the case of measuring Rₐ and RMS, the S_{dr} can be measured by means of a scanning microscope such as an AFM or an STM.

Although sharpness of the surface level variation on the substrate for the thin film photoelectric conversion device can be determined to a certain degree from a cross-sectional image of a scanning electron microscope (SEM) or a transmission electron microscope (TEM), its quantitative determination is difficult. The protrusions and recesses of the substrate for the thin film photoelectric conversion device are not necessarily linear in their sectional shape, and are usually formed by curved surfaces with variation in size and radius of curvature. Therefore, it is difficult to define the surface level variation by angles, and also difficult to quantitatively measure the sharpness thereof from the cross-sectional image. Furthermore, the cross-sectional image merely shows one of the cross sections of the substrate for the thin film photoelectric conversion device, and hence it does not necessarily represent in an exact manner the shape of the surface unevenness of the substrate for the thin film photoelectric conversion device.

In contrast, S_{dr} can be measured quantitatively even if the surface unevenness includes various variations in size and radius of curvature. Furthermore, S_{dr} is determined not by measurement of a single cross section but by three-dimensional measurement, and hence it can be said that S_{dr} represents in a more exact manner the shape of surface unevenness of the substrate for the thin film photoelectric conversion device.

It is preferable that the surface area ratio (S_{dr}) is in a range of at least 55% and at most 95%. As shown in FIG. 10 that will be described later in more detail, there is observed a correlation of Eff of the thin film photoelectric conversion device with respect to S_{dr}, and then Eff has a maximal value as S_{dr} increases. To obtain a high Eff, the S_{dr} can be used as an index for searching an optimal surface shape of the substrate for the thin film photoelectric conversion device. S_{dr} of more than 95% causes decrease in open-circuit voltage (Voc) and fill factor (FF), and hence decrease in Eff In some cases, the short-circuit current density (Jsc) is decreased, leading to decrease in Eff. The reason why S_{dr} of more than 95% causes decrease in Voc and FF may be that the surface level variation of the substrate for the thin film photoelectric conversion device becomes acute-angular, thereby causing deterioration in coverage of the silicon semiconductor layer over the transparent electrode layer, which then causes increase in contact resistance or increase in leakage current. Furthermore, the reason why S_{dr} of more than 95% causes decrease in Jsc may be that growth of the semiconductor layer over the transparent electrode layer is hindered and film quality of the semiconductor layer is deteriorated, which causes more loss owing to carrier recombination. In the case of S_{dr} of less than 55%, on the other hand, the surface unevenness of the substrate for the thin film photoelectric conversion device is small and thus the optical confinement effect is weakened, leading to decrease in short-circuit current density (Jsc) and hence decrease in Eff.

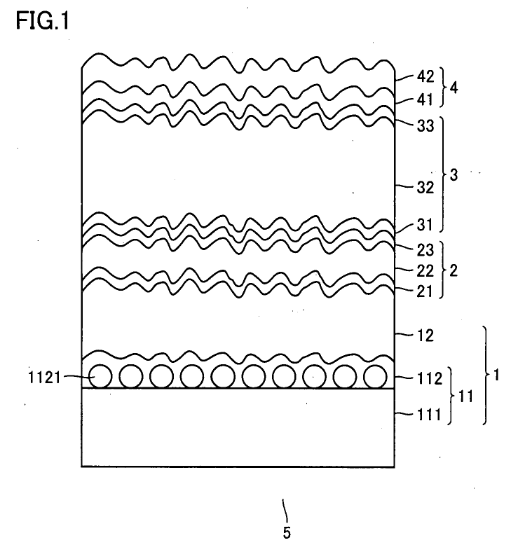

FIG. 1 is a cross section of a substrate for a thin film photoelectric conversion device and the thin film photoelectric conversion device according to an embodiment of the present invention. A substrate 1 for a thin film photoelectric conversion device includes a transparent electrode layer 12 formed on a transparent insulator base 11. A front photoelectric conversion unit 2, a back photoelectric conversion unit 3, and a back electrode layer 4 are disposed in this order on substrate 1, to form a thin film photoelectric conversion device 5.

A plate-like or sheet-like member of glass, transparent resin or the like is mainly used for transparent insulator base 11. It is particularly preferable to use a glass plate for the transparent insulator base, because the glass plate has a high transmittance and is inexpensive.

Transparent insulator base 11 is located on the light incident side of thin film photoelectric conversion device 5 and hence is preferably as transparent as possible to transmit more sunlight to be absorbed by the amorphous or crystalline photoelectric conversion unit. A glass plate can suitably be used therefor. With similar intention, it is preferable that the light incident surface of the transparent insulator base has an anti-reflection coating for reducing light reflection loss of the sunlight.

For transparent insulator base 11, it is possible to use a glass substrate alone. However, it is more preferable that transparent insulator base 111 is formed as a stacked body including a fundamental transparent base 111 such as of glass, with a smooth surface, and a transparent underlayer 112. At this time, it is preferable that transparent underlayer 112 has fine surface unevenness of a root mean square roughness in a range of 5-50 nm on its boundary neighboring to transparent electrode layer 12, and that the protrusions thereof have curved surfaces. By providing transparent underlayer 112 as described above, it is becomes easier to control the surface area ratio to a preferable value.

Transparent underlayer 112 can be formed, for example, by applying transparent fine particles 1121 along with a binder material containing a solvent. Specifically, for the transparent binder, it is possible to use metal oxides such as silicon oxide, aluminum oxide, titanium oxide, zirconium oxide, and tantalum oxide. For transparent fine particles 1121, it is possible to use silica (SiO₂), titanium oxide (TiO₂), aluminum oxide (Al₂O₃), zirconium oxide (ZrO₂), indium tin oxide (ITO), magnesium fluoride (MgF₂), or the like. As the method of applying the above-described solution to a surface of fundamental transparent base 111, it is possible to use a dipping method, a spin coat method, a bar coat method, a spray method, a die coat method, a roll coat method, a flow coat method, or the like. Particularly, the roll coat method is preferably used to form the transparent fine particles in a close-packed uniform manner. Upon completion of the application procedure, the applied thin film is immediately heated and dried.

As transparent electrode layer 12 placed on transparent insulator base 11, it is preferable to use a transparent electrode layer containing at least ZnO on its surface neighboring to a semiconductor layer formed thereon. This is because ZnO is a material having high resistance to plasma and makes it possible even at a low temperature of not more than 200° C. to form the texture causing the optical confinement effect, so that it is suitable for the thin film photoelectric conversion device including a crystalline photoelectric conversion unit. For example, from a viewpoint of obtaining the optical confinement effect of the thin film photoelectric conversion device, it is preferable that the ZnO transparent electrode layer in the substrate for the thin film photoelectric conversion device according to the present invention is formed at a deposition temperature of not more than 200° C. under a reduced pressure by a CVD method, and it has a grain size of approximately 50-500 nm and surface unevenness with level variation of approximately 20-200 nm. The deposition temperature herein refers to a temperature of a surface of the base kept in contact with a heating unit of a film-forming device.

If transparent electrode layer 12 is composed of only a thin film formed mainly with ZnO, the mean thickness of the ZnO film is preferably 0.7-5 μm and is more preferably 1-3 μm. This is because an excessively thin ZnO film hardly provides sufficient surface unevenness that effectively contributes to the optical confinement effect and also makes it difficult to obtain electrical conductivity required to serve as a transparent electrode layer, while an excessively thick ZnO film causes light absorption by the ZnO film itself, whereby reducing the quantity of light reaching to the photoelectric conversion unit through the ZnO and thus causing decrease in efficiency. Furthermore, the excessively thick film requires longer time for film formation, which increases film formation costs.

The ZnO film is suitable for the transparent electrode layer, because its surface area ratio can be controlled to an optimal value by adjusting the deposition conditions for the film. For example, in the CVD method under a reduced pressure condition, the surface area ratio of the ZnO film significantly varies depending on the deposition conditions such as temperature, pressure, and the flow rate of source gas. Therefore, the surface area ratio can be set to a desired value by controlling these conditions.

If an amorphous silicon-based material is selected for front photoelectric conversion unit 2, it is sensitive to light having a wavelength of approximately 360-800 nm. If a crystalline silicon-based material is selected for back photoelectric conversion unit 3, it is sensitive to light having a longer wavelength of up to approximately 1200 nm. Accordingly, the incident light in wider wavelength range can effectively be utilized in thin film photoelectric conversion device 5 that includes front photoelectric conversion unit 2 made of an amorphous silicon-based material and back photoelectric conversion unit 3 made of a crystalline silicon-based material disposed in this order from the light incident side. Note that the meaning of the “silicon-based” material includes not only silicon but also a semiconductor material of a silicon alloy, such as silicon carbide or silicon-germanium.

Front photoelectric conversion unit 2 is formed by stacking semiconductor layers in the order of p-type, i-type, and n-type, for example, by a plasma CVD method. Specifically, for example, there may be deposited a p-type amorphous silicon carbide layer doped with boron for determining the conductivity type at a concentration of at least 0.01 atomic %, an intrinsic amorphous silicon layer, and an n-type microcrystalline silicon layer doped with phosphorous for determining the conductivity type at a concentration of at least 0.01 atomic % in this order, which serve as one conductivity type of layer 21, a photoelectric conversion layer 22, and an opposite conductivity type of layer 23, respectively.

Back photoelectric conversion unit 3 is formed by stacking semiconductor layers in the order of p-type, i-type, and n-type, for example, by a plasma CVD method. Specifically, for example, there may be deposited a p-type microcrystalline silicon layer doped with boron for determining the conductivity type at a concentration of at least 0.01 atomic %, an intrinsic crystalline silicon layer, and an n-type microcrystalline silicon layer doped with phosphorous for determining the conductivity type at a concentration of 0.01 atomic % in this order, which serve as one conductivity type of layer 31, a photoelectric conversion layer 32, and an opposite conductivity type of layer 33, respectively.

For back electrode layer 4, it is preferable to use at least one material selected from the group consisting of Al, Ag, Au, Cu, Pt, and Cr to form at least one metal layer 42 by a sputtering method or an evaporation method. In addition, it is preferable to form a conductive oxide layer 41 of ITO, SnO₂, ZnO or the like between metal layer 42 and the photoelectric conversion unit neighboring to the metal layer, which serves as a part of back electrode layer 4. Conductive oxide layer 41 can have functions of improving adhesion between the photoelectric conversion unit and back electrode layer 4, increasing optical reflectance of back electrode layer 4, and preventing chemical deterioration of the photoelectric conversion unit.

### EXAMPLES

The examples according to the present invention will hereinafter be described in detail in comparison with comparative examples according to the conventional techniques. In the drawings, the same reference characters denote the similar members, and the description thereof will not be repeated. It should be noted that the present invention is not limited to the following examples, as long as it does not exceed the gist thereof.

A large number of substrates with different surface shapes for thin film photoelectric conversion devices were formed to evaluate the surface shapes. On each of the substrates, a stacked-layer type of silicon-based thin film photoelectric conversion device was fabricated as a thin film photoelectric conversion device. FIG. 1 shows a structure of the substrate for the thin film photoelectric conversion device and a structure of the thin film photoelectric conversion device including the substrate.

### Comparative Example 1

A substrate for a thin film photoelectric conversion device in Comparative Example 1 is commercially available one using tin oxide for a transparent electrode layer. There was purchased a substrate in which SnO₂ is deposited on a glass plate by a thermal chemical vapor deposition method (thermal CVD method) to serve as the transparent electrode layer. The substrate had a size of 910 mm×455 mm×4 mm.

The transparent electrode layer in the substrate for the thin film photoelectric conversion device in Comparative Example 1 had a measured S_{dr} of 29-42%. The S_{dr} measurement of the substrate for the thin film photoelectric conversion device was conducted by measuring an atomic force microscope (AFM) image obtained from a square area with each side of 5 μm divided into 256 segments for observation and by using formula 3 and formula 4. For the AFM measurement, there was used a non-contact mode of a Nano-R system (available from Pacific Nanotechnology, Inc.).

### Comparative Example 2

A substrate for a thin film photoelectric conversion device in Comparative Example 2 was formed as follows.

Transparent electrode layer 12 of ZnO was formed on transparent insulator base 11 made of fundamental transparent base 1111 that was a glass plate having an area of 910 mm×455 mm and a thickness of 4 mm. Transparent electrode layer 12 was formed at a deposition temperature of 190° C. under a reduced pressure by a CVD method, supplying diethyl zinc (DEZ) and water as a source gas, and a diborane gas as a dopant gas. Argon and hydrogen were additionally used as dilution gas. The ratio of water to DEZ was 2, and the ratio of diborane to DEZ was 1%. The pressure was set to 100 Pa.

The formed transparent electrode layer with a thickness of 1.5-2.5 μm in the substrate for the thin film photoelectric conversion device in Comparative Example 2 had a measured S_{dr} of more than 95%.

### Comparative Example 3

A substrate for a thin film photoelectric conversion device in Comparative Example 3 was formed as follows.

Transparent underlayer 112 containing SiO₂ fine particles 1121 was formed on fundamental transparent base 111 that was a glass plate having an area of 910 mm×455 mm and a thickness of 4 mm, to form transparent insulator substrate 11. A coating solution used for forming transparent underlayer 111 was prepared by adding tetraethoxysilane to a solution containing ethyl cellosolve, water, and suspension of spherical silica having a grain size of 50-90 nm, and by further adding thereto hydrochloric acid to hydrolyze tetraethoxysilane. After the coating solution was applied on the glass plate by a printing machine, it was dried at 90° C. for 30 minutes, and then heated at 350° C. for 5 minutes, to obtain transparent insulating substrate 11 having fine surface unevenness. Observation of the surface of transparent insulator substrate 11 by an atomic force microscope (AFM) revealed surface unevenness that reflects the shape of the fine particles and includes protrusions formed with curved surfaces.

Transparent underlayer 112 formed under the above conditions had a measured RMS of 5-50 nm, which was determined from an atomic force microscope (AFM) image obtained by observing a square area with each side of 5 μm (ISO 4287/1).

Transparent electrode layer 12 of ZnO was deposited on the formed transparent underlayer 112 to obtain the substrate for the thin film photoelectric conversion device. Transparent electrode layer 12 was formed in a similar manner as in Comparative Example 2.

The formed transparent electrode layer with a thickness of 1.5-2.5 μm in the substrate for the thin film photoelectric conversion device in Comparative Example 3 had a measured S_{dr} of more than 95%.

### Comparative Example 4

A substrate for a thin film photoelectric conversion device for Comparative Example 4 was formed as follows.

The substrate for the thin film photoelectric conversion device was formed in a similar manner and with a similar structure as in Comparative Example 3, except that the ZnO layer included therein was formed at a deposition temperature of 130° C.

The formed transparent electrode layer with a thickness of 1.5-2.5 μm in the substrate for the thin film photoelectric conversion device in Comparative Example 4 had a measured S_{dr} of less than 55%.

### Example 1

A substrate for a thin film photoelectric conversion device in Example 1 was formed as follows.

The substrate for the thin film photoelectric conversion device was formed in a similar manner and with a similar structure as in Comparative Example 3, except that the ZnO layer included therein was formed at a deposition temperature of 160° C.

The formed transparent electrode layer with a thickness of 1.5-2.5 μm in the substrate for the thin film photoelectric conversion device in Example 1 had a measured S_{dr} of 69-87%.

### Example 2

A substrate for a thin film photoelectric conversion device in Example 2 was formed as follows.

The substrate for the thin film photoelectric conversion device was formed in a similar manner and with a similar structure as in Example 1, except that the ZnO layer included therein was formed under a pressure of 20 Pa.

The formed transparent electrode layer with a thickness of 1.5-2.5 μm in the substrate for the thin film photoelectric conversion device in Example 2 had a measured S_{dr} of 66-93%.

### Example 3

A substrate for a thin film photoelectric conversion device in Example 3 was formed as follows.

The substrate for the thin film photoelectric conversion device was formed in a similar manner and with a similar structure as Example 2, except that the ZnO layer included therein was formed under a condition that the ratio of water to DEZ was 2.5.

The formed transparent electrode layer with a thickness of 1.5-2.5 μm in the substrate for the thin film photoelectric conversion device in Example 3 had a measured S_{dr} of 58-91%.

### Example 4

A substrate for a thin film photoelectric conversion device in Example 4 was formed as follows.

The substrate for the thin film photoelectric conversion device was formed in a similar manner and with a similar structure as in Example 3, except that the ZnO layer was formed under a condition that the ratio of water to DEZ was 3.5.

The transparent electrode layer with a thickness of 1.5-2.5 μm in the substrate for the thin film photoelectric conversion device in Example 4 had a measured S_{dr} of 70-80%.

### Comparative Examples and Examples

The substrate for the thin film photoelectric conversion device in each of the comparative examples and the examples was used to form thereon an amorphous silicon photoelectric conversion unit, a crystalline silicon photoelectric conversion unit, and a back electrode layer, to fabricate a stacked-layer type of photoelectric conversion device in each of the comparative examples and the examples.

Specifically, on each of the transparent electrode layers in the substrates for the thin film photoelectric conversion devices in the examples and the comparative examples, front photoelectric conversion unit 2 and back photoelectric conversion unit 3 were successively formed by a plasma CVD method. Front unit 2 was an amorphous photoelectric conversion unit that includes one conductivity type of layer 21 composed of a p-type amorphous silicon carbide layer of 15 nm thickness, photoelectric conversion layer 22 composed of an intrinsic amorphous silicon layer of 350 nm thickness, and opposite conductivity type layer of 23 composed of an n-type microcrystalline silicon layer of 15 nm thickness in this order. Back unit 3 was a crystalline silicon photoelectric conversion unit that includes one conductivity type of layer 31 composed of a p-type microcrystalline silicon layer of 15 nm thickness, photoelectric conversion layer 32 composed of an intrinsic crystalline silicon layer of 1.5 μm thickness, and opposite conductivity type of layer 33 composed of an n-type microcrystalline silicon layer of 15 nm thickness in this order. Furthermore, back electrode layer 4 was formed by depositing conductive oxide layer 41 of ZnO doped with Al and having a thickness of 90 nm and then metal layer 42 having a thickness of 200 nm with a sputtering method to complete a stacked-layer type of photoelectric conversion device.

Output properties of each stacked-layer type of photoelectric conversion device 5 obtained in the examples and the comparative examples were measured with irradiation of AM 1.5 light at energy density of 100 mW/cm².

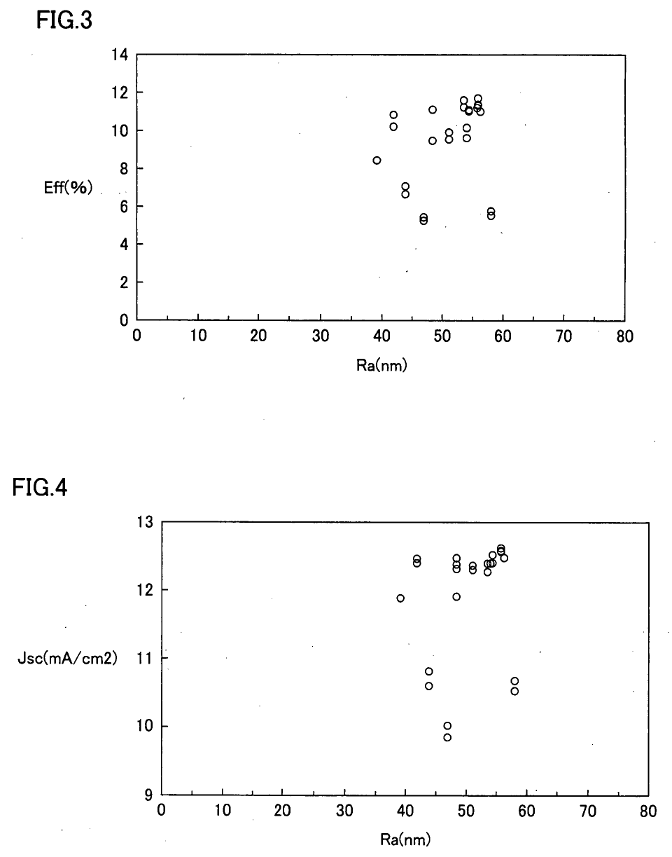

FIGS. 3-14 are correlation diagrams between properties of the formed substrates for the thin film photoelectric conversion devices in the examples and the comparative examples, and various output properties of the stacked-layer type of photoelectric conversion devices fabricated with use of these substrates in the examples and the comparative examples.

FIG. 3 is a correlation diagram showing the relation between Rₐ of the substrate for the thin film photoelectric conversion device and conversion efficiency (Eff) of the stacked-layer type of thin film photoelectric conversion device. Here, Rₐ of the substrate for the thin film photoelectric conversion device was determined by measuring an atomic force microscope (AFM) image obtained from a square area with each side of 5 μm divided into 256 segments for observation and by using formula 1. For the AFM measurement, there was used a non-contact mode of a Nano-R system (available from Pacific Nanotechnology, Inc.).

As is clear from FIG. 3, Eff shows no correlation with Rₐ, and hence Rₐ is not a favorable index of the surface shape of the substrate for the thin film photoelectric conversion device. This may be because Rₐ reflects information on height of the surface and contains no information about directions parallel to the substrate, so that it fails to represent angles or sharpness of the protrusions and recesses of the surface.

FIG. 4 is a correlation diagram showing the relation between Rₐ of the substrate for the thin film photoelectric conversion device and short-circuit current density (Jsc) of the stacked-layer type of thin film photoelectric conversion device. As is clear from FIG. 4, Jsc shows no definite correlation with Rₐ. Prior art example 1 states that larger Rₐ means larger surface unevenness and causes a larger effect of optical confinement leading to increase in Jsc. However, it was found that such a definite correlation was not observed between Rₐ and Jsc.

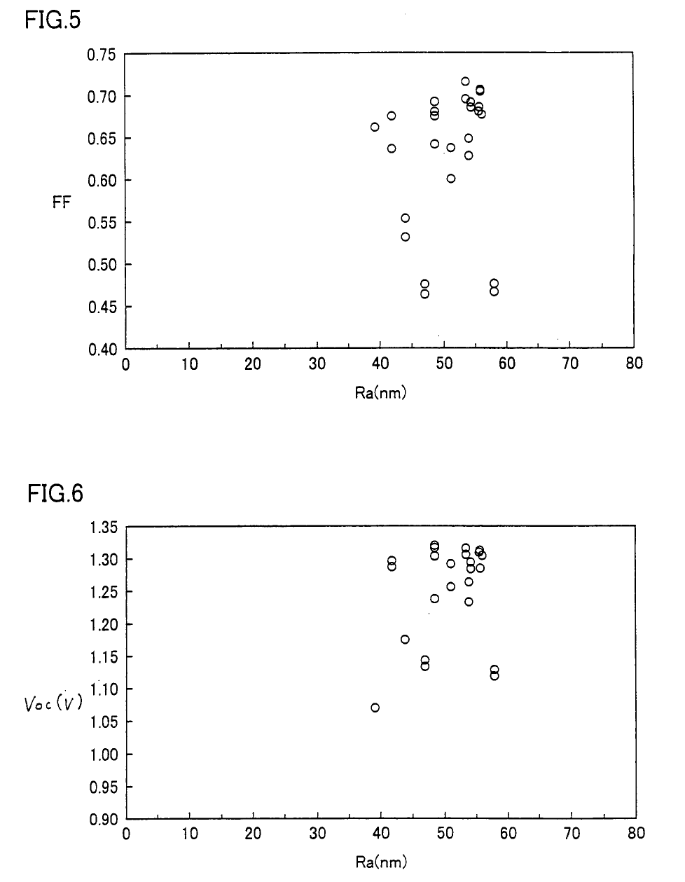

FIG. 5 is a correlation diagram showing the relation between Rₐ of the substrate for the thin film photoelectric conversion device and the fill factor (FF) of the stacked-layer type of thin film photoelectric conversion device, while FIG. 6 is a correlation diagram showing the relation between Rₐ of the substrate for the thin film photoelectric conversion device and the open-circuit voltage (Voc) of the stacked-layer type of thin film photoelectric conversion device.

As is clear from FIG. 5, FF shows no correlation with Rₐ. As is clear from FIG. 6, Voc also shows no correlation with Rₐ. Furthermore, even when Rₐ is less than 2 μm, there can be observed significant decrease in FF or Voc. This means that when growth of the thin film semiconductor layer is hindered and film quality is deteriorated, not only the short-circuit current density (Jsc) but also Voc and FF as are decreased and hence Eff is decreased. In contrast to prior art example 1, therefore, it was revealed that even when Rₐ is less than 2 μm, it is probable that growth of the thin film semiconductor layer may be hindered and film quality may be deteriorated.

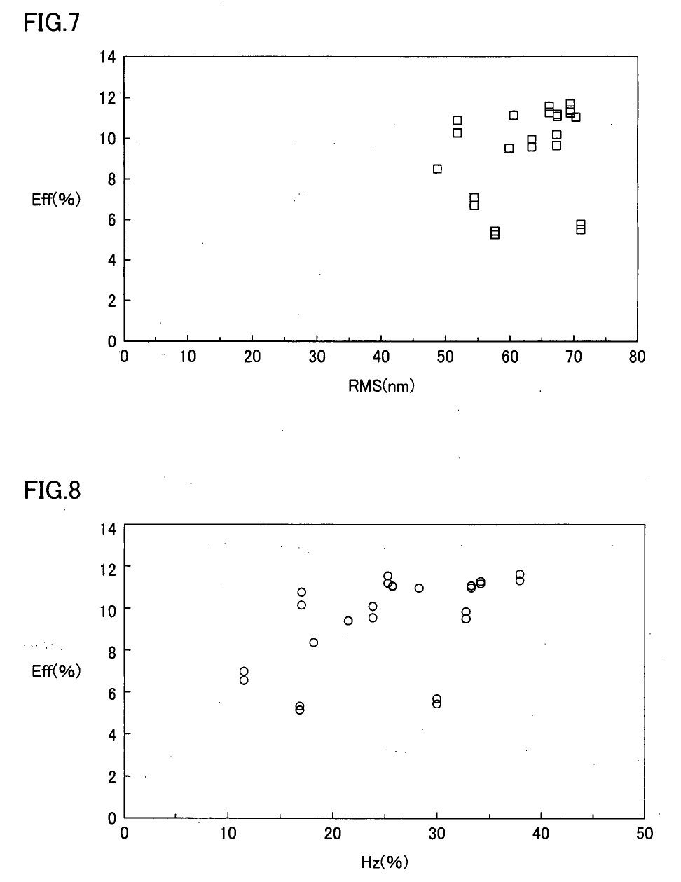

FIG. 7 is a correlation diagram showing the relation between RMS of the substrate for the thin film photoelectric conversion device and Eff of the stacked-layer type of thin film photoelectric conversion device. Here, RMS of the substrate for the thin film photoelectric conversion device was determined by measuring an atomic force microscope (AFM) image obtained from a square area with each side of 5 μm divided into 256 segments for observation and by using formula 2. For the AFM measurement, there was used a non-contact mode of a Nano-R system (available from Pacific Nanotechnology, Inc.).

As is clear from FIG. 7, no correlation is observed between RMS and Eff. Accordingly, it was found that RMS is not a favorable index of the surface shape of the substrate for the thin film photoelectric conversion device.

Similarly as Rₐ, the RMS reflects information on height of the surface and contains no information on directions parallel to the substrate, so that it fails to represent angles or sharpness of protrusions and recesses of the surface. Therefore, it cannot be determined whether there exist acute-angular protrusions or whether there exist gorge-like recesses. This may be the reason for no correlation observed between RMS and Eff.

As a result of investigation as to the relation of each of Jsc, FF and Voc with RMS, there was observed no correlation. It was therefore revealed that there is no correlation between RMS and any parameter of the properties of the thin film photoelectric conversion device.

FIG. 8 is a correlation diagram showing the relation between the haze ratio (Hz) of the substrate for the thin film photoelectric conversion device and Eff of the stacked-layer type of thin film photoelectric conversion device. Hz of the substrate for the thin film photoelectric conversion device was measured with use of a C light source by means of a haze meter (an NDH5000W-type turbidity-cloudiness meter available from Nippon Denshoku Industries Co., Ltd.).

As is clear from FIG. 8, no correlation is observed between Hz and Eff. It was therefore revealed that Hz is not a favorable evaluation index of the surface shape of the substrate for the thin film photoelectric conversion device. Hz shows the degree of averaged light scattering over a wide wavelength range, and hence fails to definitely reflect information on periodicity of the surface unevenness. Accordingly, it cannot definitely reflect angles or sharpness of protrusions and recesses of the surface. This may be a reason for no correlation observed between Hz and Eff.

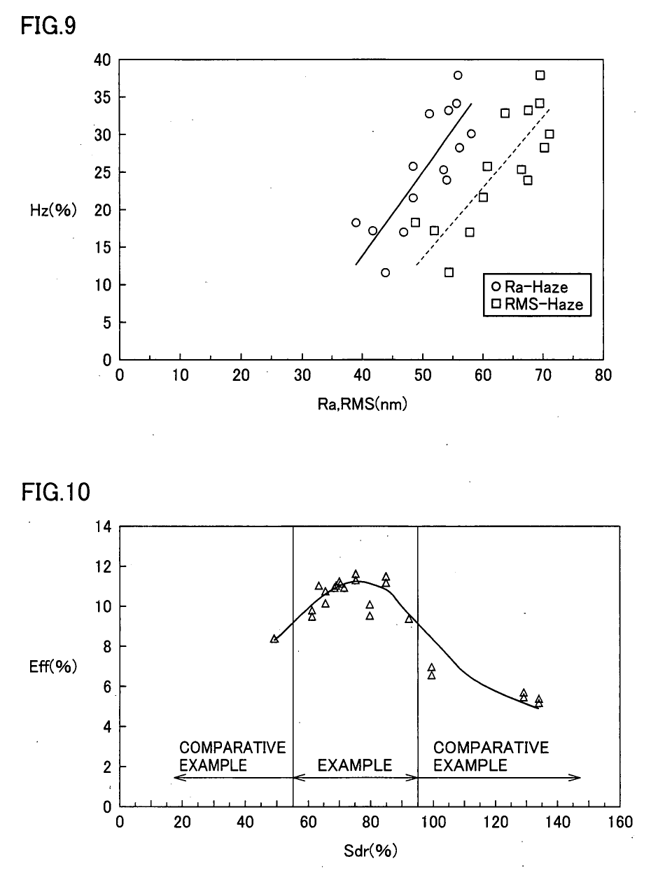

FIG. 9 is a correlation diagram showing the relations between Hz and Rₐ and between Hz and RMS of the substrate for the thin film photoelectric conversion device. Each relation between Hz and Rₐ and between Hz and RMS shows a positive linear correlation. Accordingly, Rₐ, RMS and Hz cannot be regarded as independent evaluation indices of the surface unevenness of the substrate for the thin film photoelectric conversion device, and it was found that they show almost the same phenomenon with respect to the surface unevenness. It can be said that, if Rₐ has no correlation with Eff of the thin film photoelectric conversion device, RMS and Hz also have no correlation with Eff.

FIG. 10 is a correlation diagram showing the relation between S_{dr} of the substrate for the thin film photoelectric conversion device and Eff of the stacked-layer type of thin film photoelectric conversion device. S_{dr} of the substrate for the thin film photoelectric conversion device was determined by measurement with an AFM and by using formula 3 and formula 4 similarly as in Comparative Example 1.

As is clear from FIG. 10, Eff shows a correlation with S_{dr}, where Eff has a maximal value with respect to S_{dr}. Specifically, Eff shows relatively higher values of at least 9% while S_{dr} is in a range of at least 55% and at most 95%. In order to obtain a high Eff, therefore, S_{dr} can be used as an index capable of showing an optimal surface shape of the substrate for the thin film photoelectric conversion device. When S_{dr} exceeds 95%, it is considered that the surface level variation becomes acute-angular and thus causes deterioration in coverage of the silicon semiconductor layer over the transparent electrode layer or deterioration in film quality of the silicon semiconductor layer, leading to decrease in Eff. When S_{dr} is less than 55%, on the other hand, the surface level variation becomes smaller and thus weakens the optical confinement effect, leading to decrease in Jsc and hence decrease in Eff.

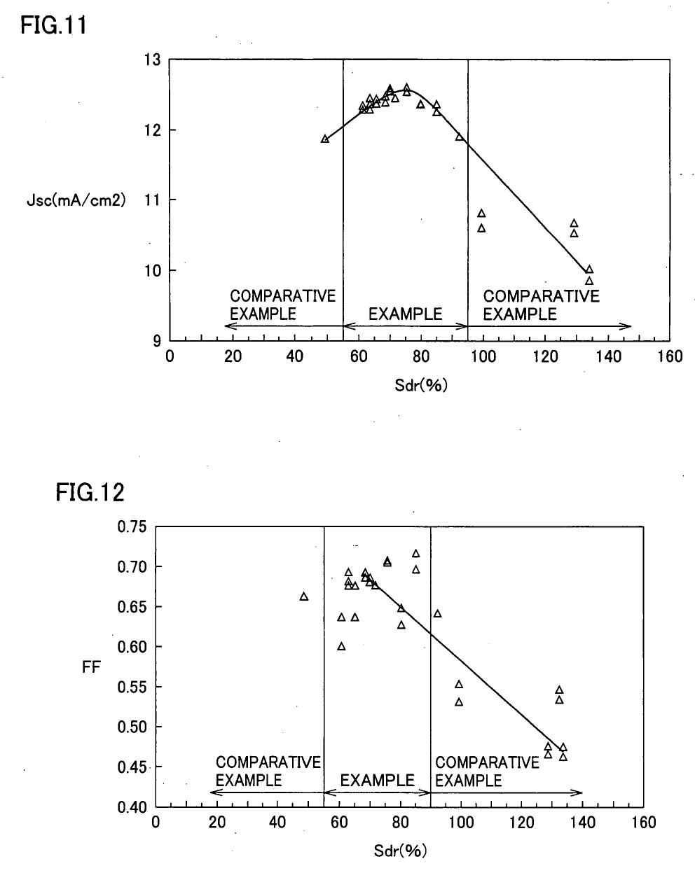

FIG. 11 is a correlation diagram showing the relation between S_{dr} of the substrate for the thin film photoelectric conversion device and Jsc of the stacked-layer type of thin film photoelectric conversion device. As is clear from FIG. 11, Jsc shows a correlation with S_{dr}, where Jsc has a maximal value with respect to S_{dr}. In order to obtain a high Jsc as well as a high Eff, therefore, S_{dr} can be used as an index capable of showing an optimal surface shape of the substrate for the thin film photoelectric conversion device. The reason why Jsc increases as S_{dr} increases in a range smaller than approximately 75% is that the surface unevenness of the substrate for the thin film photoelectric conversion device becomes large and increases the optical confinement effect. The reason why Jsc decreases as S_{dr} increases in a range larger than approximately 75% is that the surface level variation becomes acute-angular and causes deterioration in coverage of the silicon semiconductor layer over the transparent electrode layer and hence increase in loss owing to contact resistance, or causes deterioration in film quality of the silicon semiconductor layer and hence increase in loss owing to carrier-recombination current.

FIG. 12 is a correlation diagram showing the relation between S_{dr} of the substrate for the thin film photoelectric conversion device and FF of the stacked-layer type of thin film photoelectric conversion device. As is clear from FIG. 12, FF shows a correlation with respect to S_{dr}, where FF decreases approximately linearly as S_{dr} increases. In order to obtain a high FF as well as a high Eff, therefore, S_{dr} can be used as an index capable of showing an optimal surface shape of the substrates for the thin film photoelectric conversion device.

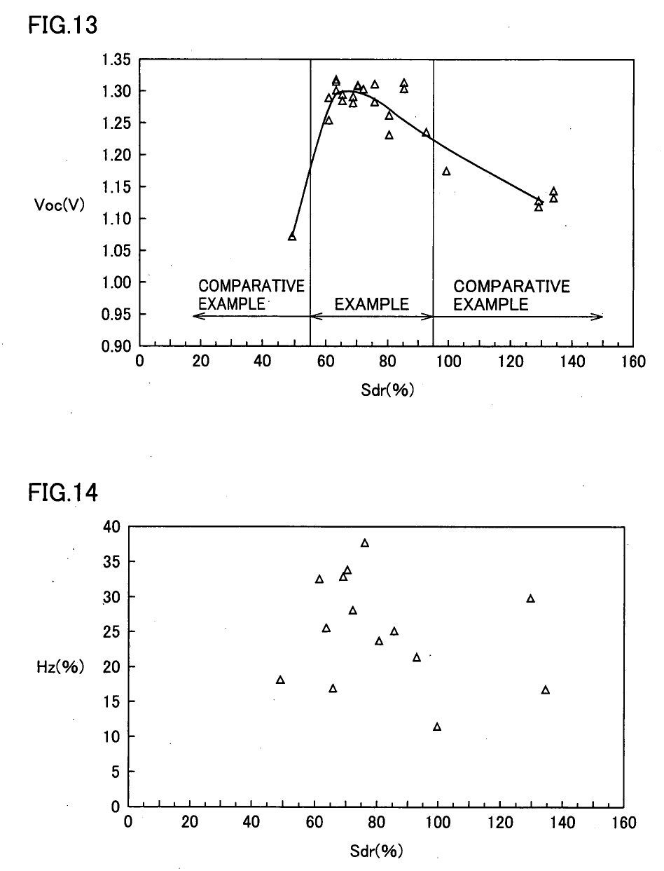

FIG. 13 is a correlation diagram showing the relation between S_{dr} of the substrate for the thin film photoelectric conversion device and Voc of the stacked-layer type of thin film photoelectric conversion device. As is clear from FIG. 13, Voc shows a correlation with S_{dr}, where Voc has a maximal value with respect to S_{dr}. In order to obtain a high Voc as well as a high Eff, therefore, S_{dr} can be used as an index capable of showing an optimal surface shape of the substrate for the thin film photoelectric conversion device.

FIG. 14 is a correlation diagram showing the relation between Hz and S_{dr} of the substrate for the thin film photoelectric conversion device. Hz shows no correlation with S_{dr}. Accordingly, it was revealed that S_{dr} and Hz can be regarded as independent evaluation indices of the surface unevenness of the substrate for the thin film photoelectric conversion device.

1. A substrate for a thin film photoelectric conversion device, comprising a transparent insulator base and a transparent electrode layer deposited thereon, wherein a surface of the transparent electrode layer has a surface area ratio of at least 55% and at most 95%.

2. The substrate for the thin film photoelectric conversion device according to claim 1, wherein said transparent electrode layer contains at least zinc oxide.

3. The substrate for the thin film photoelectric conversion device according to claim 1, wherein said transparent insulator base is mainly composed of a glass plate.

4. A thin film photoelectric conversion device, comprising at least one photoelectric conversion unit and a back electrode layer stacked in this order on the substrate defined by any of claims 1-3.
